(19) United States
(12) Patent Application Publication
(10) Pub. No.: US 2025/0349627 A1
(43) Pub. Date: Nov. 13, 2025

(54) SACRIFICIAL TEST PAD

(71) Applicant: Taiwan Semiconductor Manufacturing Company, Ltd., Hsin-Chu (TW)

(72) Inventors: Tzu-Ting Liu, Taoyuan City (TW); Wen-Chiung Tu, New Taipei City (TW); Ming-Wei Lee, Taichung City (TW); Chen-Chiu Huang, Taichung City (TW); Dian-Hau Chen, Hsinchu (TW)

(21) Appl. No.: 19/278,938

(22) Filed: Jul. 24, 2025

Related U.S. Application Data
(63) Continuation of application No. 18/440,483, filed on Feb. 13, 2024.
(60) Provisional application No. 63/591,226, filed on Oct. 18, 2023.

(51) Int. Cl. H01L 21/66; H01L 23/00

(52) U.S. Cl. CPC H01L 22/32; H01L 24/02; H01L 24/05; H01L 22/14; H01L 24/08; H01L 24/80; H01L 2224/02321; H01L 2224/0235; H01L 2224/0239; H01L 2224/05018; H01L 2224/05024; H01L 2224/05027; H01L 2224/05083; H01L 2224/05546; H01L 2224/05558; H01L 2224/05569; H01L 2224/05571; H01L 2224/05573; H01L 2224/05624; H01L 2224/05647; H01L 2224/05655; H01L 2224/05657; H01L 2224/05666; H01L 2224/08145; H01L 2224/08225; H01L 2224/80011; H01L 2224/80895; H01L 2224/80896; H01L 2924/01013; H01L 2924/01022; H01L 2924/01027; H01L 2924/01028; H01L 2924/01029

(57) ABSTRACT

The present disclosure provides a redistribution structure that includes a metal line, a first dielectric layer disposed over the metal line, a first etch stop layer (ESL) disposed over the first dielectric layer, a second dielectric layer disposed over the first ESL, and a conductive via extending through the second dielectric layer, the first ESL and the first dielectric layer to contact the metal line. A lower portion of the second dielectric layer extends downward through the first ESL and the first dielectric layer and partially into the metal line.

### PRIORITY DATA

This application is a continuation of U.S. Non-Provisional patent application Ser. No. 18/440,483, filed Feb. 13, 2024, which claims priority to U.S. Provisional Patent Application No. 63/591,226, filed Oct. 18, 2023, the entirety of which are incorporated herein by reference for all purposes.

### BACKGROUND

A redistribution layer (RDL) is an extra metal layer that redirects signals from pads of an integrated circuit (IC) die to other locations for better access. Because an RDL structure is usually on top of a die, it usually is home of test pads or probing pads, such as wafer acceptance test (WAT) pads. By probing the WAT pads, process control monitoring data is generated to improve yield and reduce defects. A test pad may be substantially larger than line pitches in the RDL and take up space that can be used to place functional pads for three-dimensional (3D) packaging.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method 100 for forming a sacrificial test pad for testing purposes and subsequently removing the same to make room for functional pads, according to various aspects of the present disclosure.

FIGS. 2-18 include fragmentary cross-sectional views of a work-in-progress (WIP) structure undergoing various stages of operations during the performance of the method 100 in FIG. 1, according to various aspects of the present disclosure.

FIG. 19 illustrates a flowchart of a method 300 for forming a sacrificial test pad for testing purposes and subsequently removing a portion thereof to make room for functional pads, according to various aspects of the present disclosure.

FIGS. 20-24 include fragmentary cross-sectional views of a WIP structure undergoing various stages of operations during the performance of the method 300 in FIG. 19, according to various aspects of the present disclosure.

FIG. 25 illustrates a flowchart of a method 400 for forming a sacrificial test pad for testing purposes and subsequently patterning the same to make room for functional pads, according to various aspects of the present disclosure.

FIGS. 26-30 include fragmentary cross-sectional views of a WIP structure undergoing various stages of operations during the performance of the method 400 in FIG. 25, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A redistribution layer (RDL) is an extra metal layer that redirects signals from pads of an integrated circuit (IC) die to other locations for better access. Because an RDL structure is usually on top of a die and is formed at the end of the back end process, it usually is home of test pads or probing pads, such as wafer acceptance test (WAT) pads. By probing the WAT pads, process control monitoring data is generated to improve yield and reduce defects. Existing testing pads are usually substantially larger than a line pitch in the RDL. While insertion of testing pads is necessary for probing, their presence may increase distances between metal features and they take up space where vias may land. Implementation of testing pads poses little or no problem for single die packaging or two-dimensional (2D) packaging. However, it is less compatible with three-dimensional (3D) packaging. The testing pads not only increase pitches of metal features and may prevent efficient placement of vias and contact pads for device stacking.

The present disclosure provides a method that forms a sacrificial test pad that is available for probe testing during acceptance test and removes or trims the sacrificial test pad to increase via landing area. An example process includes depositing a first dielectric layer over a metal line in a redistribution layer, depositing a first etch stop layer (ESL) over the first dielectric layer, forming a test contact opening through the first dielectric layer and the first ESL to expose a portion of the metal line, forming a sacrificial test pad over the test contact opening, performing a test by causing a probe to contact the sacrificial test pad, after the performing of the test, removing the sacrificial test pad to expose the test contact opening, and after the removing of the test pad, depositing a second dielectric layer over the first ESL and the test contact opening. In other example processes, the sacrificial test pad is planarized or patterned to have a smaller form factor such that it does not hinder landing of contact vias.

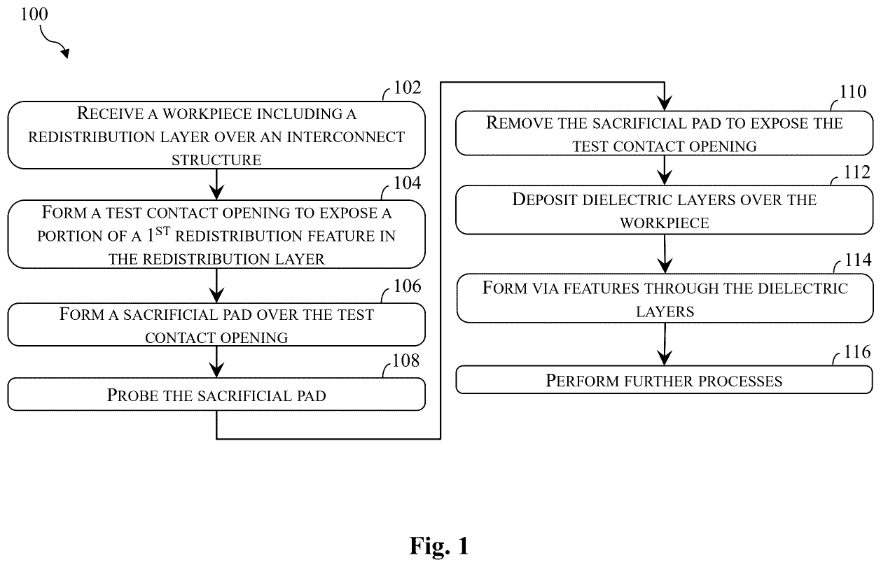

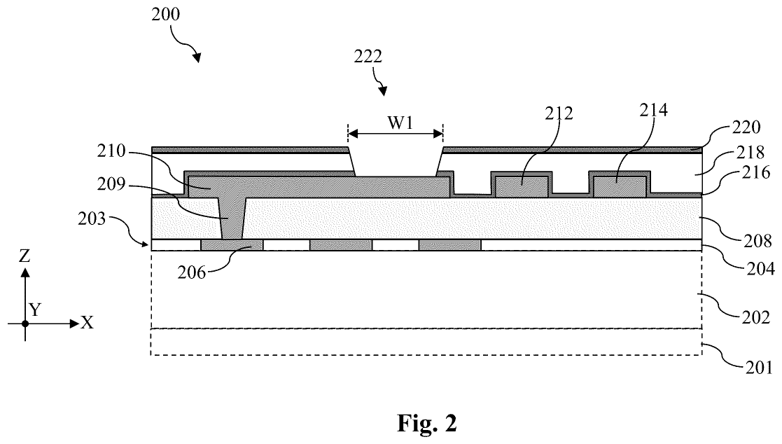

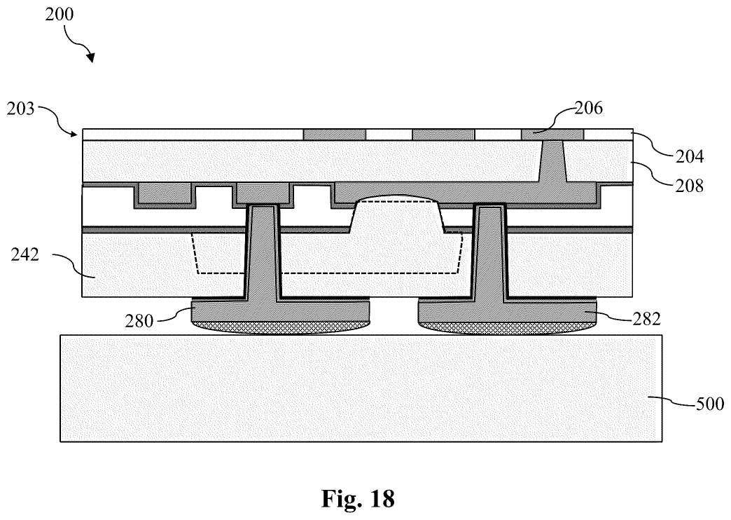

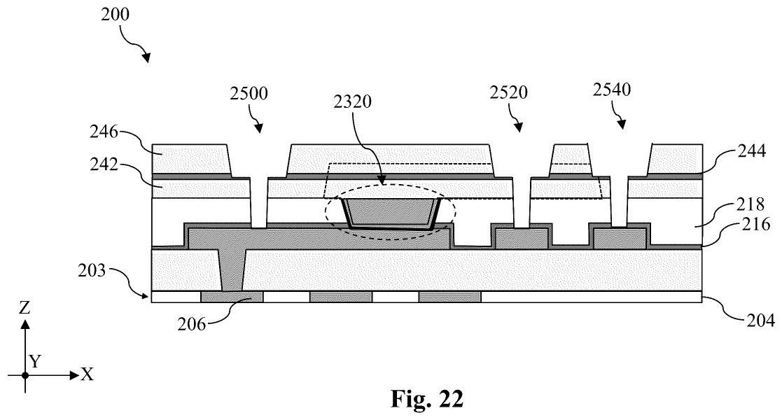

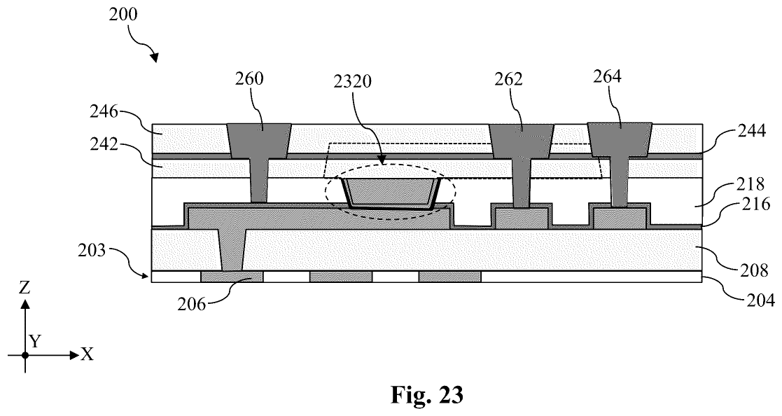

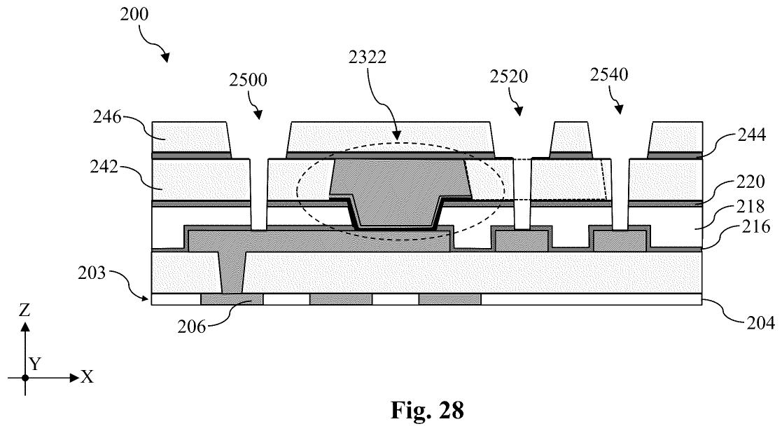

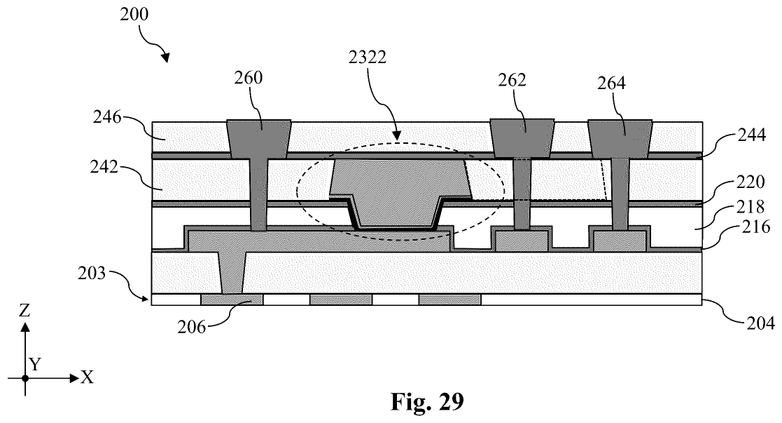

The various aspects of the present disclosure will now be described in more detail with reference to the figures. In that regard, FIGS. 1, 19 and 25 are flowcharts illustrating method 100, 300 and 500 for forming a test pad that is subsequently removed, planarized or patterned according to various aspects of the present disclosure. Methods 100, 300 and 400 are merely examples and are not intended to limit the present disclosure to what is explicitly illustrated in method 100, 300 or 400. Additional steps may be provided before, during and after method 100, 300 or 400, and some steps described can be replaced, eliminated, or moved around for additional embodiments of the respective method. Not all steps are described herein in detail for reasons of simplicity. Method 100 is described below in conjunction with FIGS. 2-18, which are fragmentary cross-sectional views of a work-in-progress (WIP) structure 200 (or an intermediate structure 200) at different stages of fabrication according to embodiments of method 100. Method 300 is described below in conjunction with FIGS. 2-7 and 20-24, which are fragmentary cross-sectional views of a WIP structure 200 at different stages of fabrication according to embodiments of method 300. Method 400 is described below in conjunction with FIGS. 2-7 and 26-30, which are fragmentary cross-sectional views of a WIP structure 200 at different stages of fabrication according to embodiments of method 400. Because the WIP structure 200 will be fabricated into a semiconductor structure 200 upon conclusion of the fabrication processes, the WIP structure 200 may be referred to as a semiconductor structure 200 as the context requires. Additionally, throughout the present application and across different embodiments, like reference numerals denote like features with similar structures and compositions, unless otherwise excepted.

Referring to FIGS. 1 and 2, method 100 includes a block 102 where a WIP structure 200 is received. The WIP structure 200 includes a top metal layer 203 over an interconnect structure 202. Referring to FIG. 2, the WIP structure 200 includes a substrate 201, an interconnect structure 202 disposed over the substrate 201, and a top metal layer 203 over the interconnect structure 202. As will be described further below, the substrate 201 is formed of a semiconductor material and has undergone front-end-of-line (FEOL) processes. Such FEOL processes may form various transistors on the substrate 201 to serve different functions. For example, these various transistors may form a central processing unit (CPU), a graphics process unit (GPU), access transistors for memory devices, or image signal processing (ISP) circuitry. The transistors may be planar transistors or multi-gate transistors. A planar device refers to a device having a gate structure that engages a planar surface of a semiconductor active region. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, or other nanostructures and for that reasons, a GAA transistor may also be referred to as a nanowire transistor or a nanosheet transistor. The interconnect structure 202 includes multiple metal layers and is part of a back-end-of-the line (BEOL) structure. The top metal layer 203 may include a top metal feature 206 disposed in a top dielectric layer 204.

In some embodiments, the substrate 201 includes silicon (Si). Alternatively or additionally, substrate 201 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 201 includes one or more group III-V materials, one or more group II-IV materials, or combinations thereof. In some implementations, the substrate 201 is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. Because method 100 is performed to layers and structures over the substrate 201 and the interconnect structure 202, the substrate 201 and the interconnect structure 202 are shown only in FIG. 2 in dotted lines and are omitted from the rest of the drawings for simplicity.

The interconnect structure 202 includes about five (5) to about twenty (20) metal layers (or metallization layers). Each of the metal layers of the interconnect structure 202 include multiple vias and metal lines embedded in an intermetal dielectric (IMD) layer. The vias and metal lines may be formed of titanium (Ti), ruthenium (Ru), nickel (Ni), cobalt (Co), copper (Cu), molybdenum (Mo), tungsten (W), or aluminum (Al). In one embodiment, they are formed of copper (Cu). The IMD layer may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the IMD layer includes silicon oxide.

Like the IMD layers in the interconnect structure 202, the top dielectric layer 204 of the top metal layer 203 may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the top dielectric layer 204 includes silicon oxide. The top metal feature 206 in the top metal layer 203 may include copper (Cu), nickel (Ni), cobalt (Co), titanium (Ti), aluminum (Al), or aluminum-copper (Al—Cu).

The WIP structure 200 in FIG. 2 includes a passivation layer 208 over the top metal layer 203. The passivation layer 208 may include silicon nitride and may have a thickness between about 1 μm and about 2 μm to shield stress from the structure lying below. A redistribution layer is disposed over the passivation layer 208. In the fragmentary cross-sectional view in FIG. 2, the redistribution layer includes a first redistribution feature 210, a second redistribution feature 212, and a third redistribution feature 214. Each of the first redistribution feature 210, the second redistribution feature 212 and the third redistribution feature 214 redirects signals to other locations for better access or spacing. When a redistribution feature is elongated as the first redistribution feature 210 shown in FIG. 2, it may also be referred to as a metal line. In some embodiments, the first redistribution feature 210, the second redistribution feature 212 and the third redistribution feature 214 may include copper (Cu), nickel (Ni), cobalt (Co), titanium (Ti), or aluminum (Al). In one embodiment, they include copper (Cu). In some embodiments represented in FIG. 2, a contact via 209 extends continuously from the first redistribution feature 210 through the passivation layer 208 to contact the top metal feature 206. To prevent oxygen diffusion or electromigration, a dielectric liner 216 is disposed along top surfaces and sidewalls of the first redistribution feature 210, the second redistribution feature 212 and the third redistribution feature 214. In some instances, the dielectric liner 216 may include silicon nitride and have a thickness between about 100 nm and about 200 nm. As shown in FIG. 2, a first dielectric layer 218 and a first etch stop layer (ESL) 220 are sequentially deposited over the dielectric liner 216. In some embodiments, the first dielectric layer 218 may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the first dielectric layer 218 includes silicon oxide. The first ESL 220 may include silicon nitride. The first dielectric layer 218 may have a thickness between about 300 nm and about 700 nm. The first ESL 220 may have a thickness between about 300 nm and about 1000 nm.

Referring to FIGS. 1 and 2, method 100 includes a block 104 where a test contact opening 222 is formed to expose a portion of a first metal line 206 in the top metal layer 203. At block 104, the first ESL 220 and the first dielectric layer 218 are patterned to form the test contact opening 222 to expose the top metal feature 206. While not explicitly shown in the figures, the patterning at block 104 includes a combination of photolithography and etch steps. For example, at least one hard mask is deposited over the first ESL 220 using CVD, flowable CVD (FCVD), or a suitable process. A photoresist layer is then deposited over the at least one hard mask layer using spin-on coating. The deposited photoresist layer may undergo an pre-exposure baking process, exposure to radiation reflected from or transmitted through a photomask, a post-exposure baking process, and developing process, so as to form a patterned photoresist. The at least one hard mask layer is then etched using the patterned photoresist as an etch mask to form a patterned hard mask. The patterned hard mask is then applied as an etch mask to etch the first ESL 220 to form the test contact opening 222. Appropriate etch process at block 104 may be a dry etch process, a wet etch process, or a combination thereof. In some embodiments, the etch process at block 104 may be a dry etch process (e.g., a reactive ion etching (RIE) process) that includes use of an oxygen-containing gas (e.g., O₂), a fluorine-containing gas (e.g., SF₆ or NF₃), or a chlorine-containing gas (e.g., Cl₂ and/or BCl₃). As shown in FIG. 2, the first contact opening 222 extends completely through the first ESL 220 and the first dielectric layer 218 to expose the top metal feature 206. In some instances, the test contact opening 222 has a first width W1 along a horizontal direction with respect to the substrate 201. The first width W1 may be between about 10 μm and about 20 μm. While not explicitly shown in the figure, the test contact opening 222 may be circular in a top view along the Z direction. When the test contact opening 222 is circular or substantially circular, the first width WI is a diameter of the circular shape of the test contact opening 222.

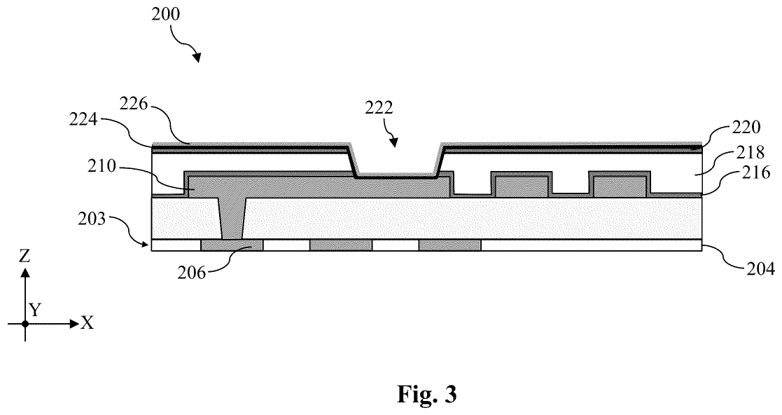

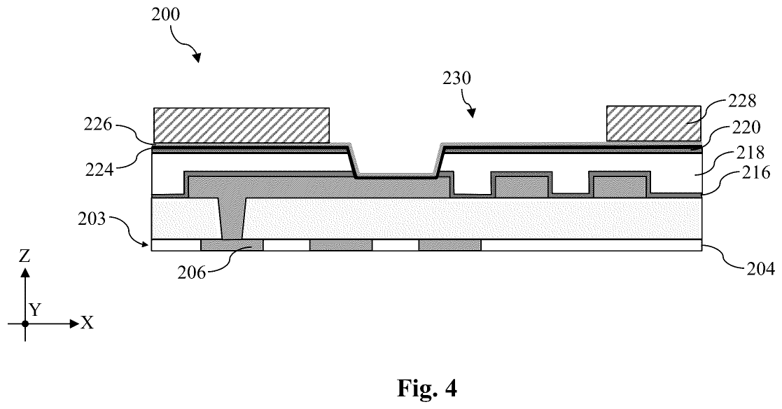

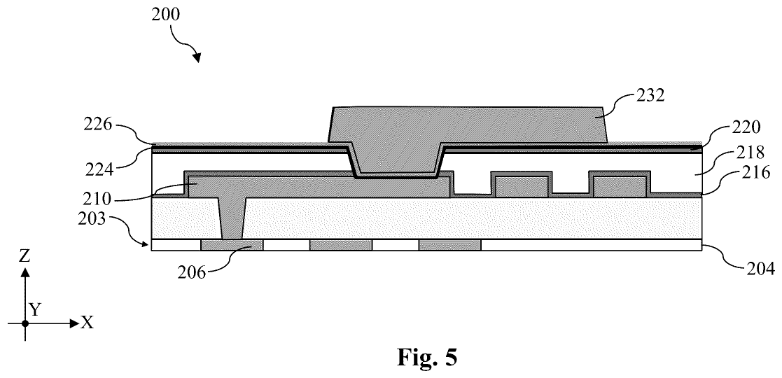

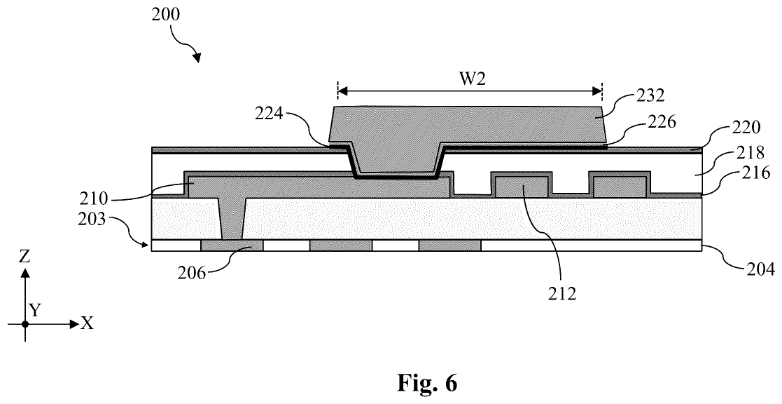

Referring to FIGS. 1 and 3-6, method 100 includes a block 106 where a sacrificial pad 232 is formed over the test contact opening 222. Operations at block 116 may include deposition of a barrier layer 224 (shown in FIG. 3), deposition of a seed layer 226 over the barrier layer 224 (shown in FIG. 3), formation of a patterned mask 228 over the seed layer 226 (shown in FIG. 4), deposition of a metal filler 232 over the seed layer 226 (shown in FIG. 5), and patterning of the barrier layer 224 and the seed layer 226 (shown in FIG. 6). In some embodiments, the sacrificial pad 232 is formed using electroplating or electroless plating.

Referring to FIG. 3 the barrier layer 224 is conformally deposited over the WIP structure 200, including over the test contact opening 222. The barrier layer 224 may include titanium (Ti), tantalum (Ta), titanium nitride (TiN), or tantalum nitride (TaN) and may have a thickness between about 100 Å and about 300 Å. The barrier layer 224 may be deposited using physical vapor deposition (PVD), metalorganic chemical vapor deposition (MOCVD), or CVD. A seed layer 226 is then deposited over the barrier layer 224. The seed layer 226 includes copper (Cu) and may be deposited using PVD or CVD and may have a thickness between about 400 Å and about 600 Å.

Reference is then made to FIG. 4. After the seed layer 226 is deposited, a patterned mask 228 is formed over the seed layer 226. The patterned mask 228 may include a photoresist layer or a bottom antireflective coating (BARC) layer. In an example process, material for the patterned mask 228 is deposited over the seed layer 226 using spin-on coating or flowable CVD (FCVD). Thereafter, photolithography techniques may be used to pattern the material into the patterned mask 228, which defines a pad opening 230. After the patterned mask 228 is formed, plating (e.g., electroplating or electroless plating) is performed to deposit copper (Cu), gold (Au), titanium tungsten (TiW), nickel (Ni), or platinum (Pt) over the seed layer 226 exposed in the pad opening 230 in the patterned mask 228. In one embodiment, aluminum-copper (Al—Cu) is deposited over the seed layer 226. The deposition of the conductive layer in the pad opening 230 forms the sacrificial pad 232 after the removal of the patterned mask 228. In some embodiments not explicitly shown in FIG. 5, a solder feature may be formed over the sacrificial pad 232. The solder feature may include tin (Sn). After the sacrificial pad 232 is formed in the pad opening 230, the patterned mask 228 is selectively removed by ashing or selective etching, as shown in FIG. 5. Reference is made to FIG. 6. After the patterned mask 228 is removed, the barrier layer 224 and the seed layer 226 that are not covered by the sacrificial pad 232 are selectively etched away, as shown in FIG. 6. A illustrated in FIG. 6, the sacrificial pad 232 is spaced apart from the first ESL 220, the first dielectric layer 218, the dielectric liner 216, and the first redistribution feature 210 by the barrier layer 224 and the seed layer 226. For case of reference, the sacrificial pad 232 and the barrier layer 224 and the seed layer 226 covered by the sacrificial pad 232 may be collectively referred to as the sacrificial pad 232.

The sacrificial pad 232 may be rectangular or square in shape in a top view. In FIG. 6, the sacrificial pad 232 has a second width W2 along the X direction or the Y direction. The second width W2 may be between about 40 μm and 60 μm. Because the sacrificial pad 232 need to be large enough to accommodate the probing operation at block 108, it is substantially larger than the test contact opening 222. It some instances, it can be large enough to take up space and hinder via landing. For example, the sacrificial pad 232 at least overhangs the second redistribution feature 212 and prevent vias to land on the second redistribution feature 212.

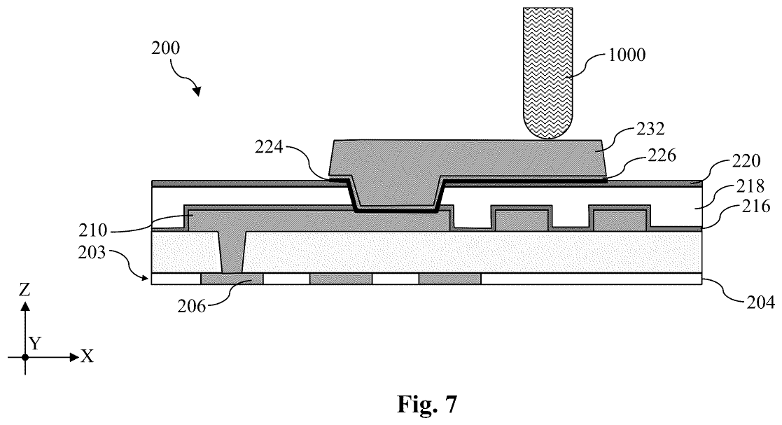

Referring to FIGS. 1 and 7, method 100 includes a block 108 where the sacrificial pad 232 is probed. At block 108, a probe 1000 is caused to contact the sacrificial pad 232. In some embodiments, the probe 1000 is one of many probes in a probe card. By having a physical and electrical contact between the probe 1000 and a top surface of the sacrificial pad 232, an electronic test system may perform an automated integrated circuit testing. The probe 1000 may also be referred to as an electrical connector or a pin. After the probing at block 108, all testing that requires the presence of the sacrificial pad 232 has been performed.

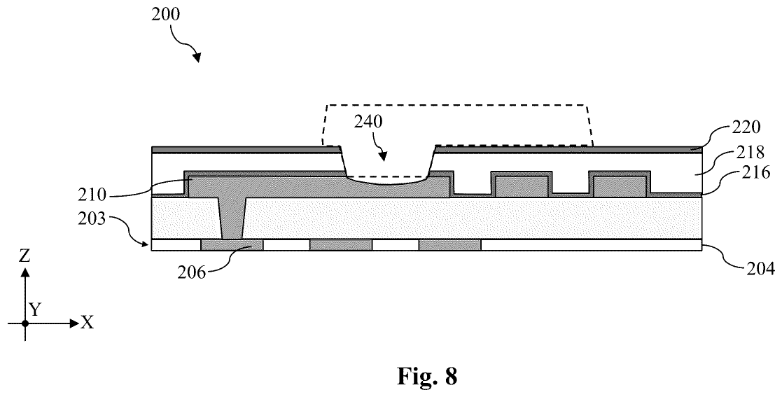

Referring to FIGS. 1 and 8, method 100 includes a block 110 wherein the sacrificial pad 232 is removed to expose the test contact opening 222. Because all the testing that requires the presence of the sacrificial pad 232 has been performed at this point, operations at block 110 are performed to remove the sacrificial pad 232 to release the space it once occupies. At block 110, each of the sacrificial pad 232, the seed layer 226 and the barrier layer 224 may be selectively removed by a dry etch, a wet etch, or a combination thereof. For example, the sacrificial pad 232 and the seed layer 226 may be selectively etched away using a wet etchant that includes nitric acid, iron chloride, hydrogen chloride, sulfuric acid, potassium dichoromate. For another example, the barrier layer 224 may be selectively etched away using a wet etchant that includes ammonium hydroxide, hydrogen peroxide, hydrofluoric acid, or nitric acid. Because the chemical that etches the sacrificial pad 232 also etches the first redistribution feature 210, a recess 240 may be formed. The recess 240 extends into the first redistribution feature 210. That is, a bottom surface of the recess 240 is lower than a top surface of the first redistribution feature 210. The location of the removed sacrificial pad 232 is marked using dotted lines.

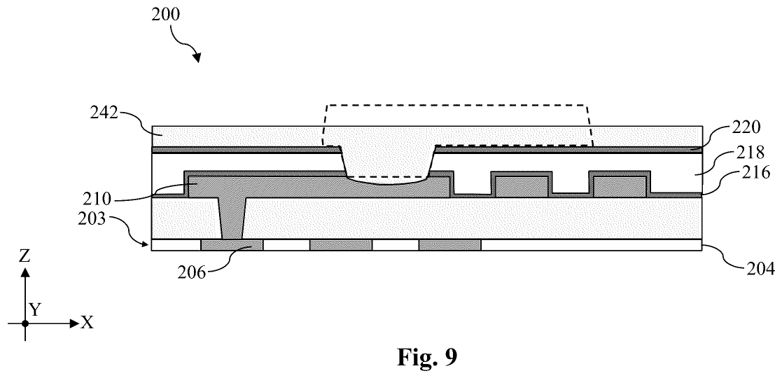

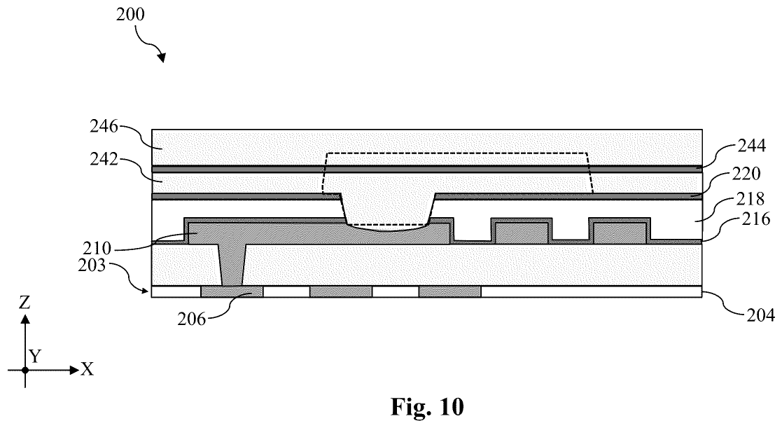

Referring to FIGS. 1 and 9-10, method 100 includes a block 112 where dielectric layers are deposited over the WIP structure 200. As illustrated in FIGS. 9 and 10, block 112 deposits a second dielectric layer 242 over the first ESL 220 as well as over the recess 240, a second ESL 244 over the second dielectric layer 242, and a third dielectric layer 246 over the second ESL 244. In some embodiments, the second dielectric layer 242 and the third dielectric layer 246 may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. The second dielectric layer 242 and the third dielectric layer 246 may be deposited using spin-on coating or flowable CVD (FCVD). The second ESL 244 may include silicon nitride. In some implementations, the second dielectric layer 242 has a thickness between about 0.25 μm and about 1.5 μm. The second ESL 244 has a thickness between about 50 nm and about 100 nm. The second ESL 244 may be deposited using PVD or CVD. It is noted that a lower portion of the second dielectric layer 242 extends through the first ESL 220 and the first dielectric layer 218 and into the recess 240. That is, a lowest surface of the second dielectric layer 242 is lower than the top surface of the first redistribution feature 210.

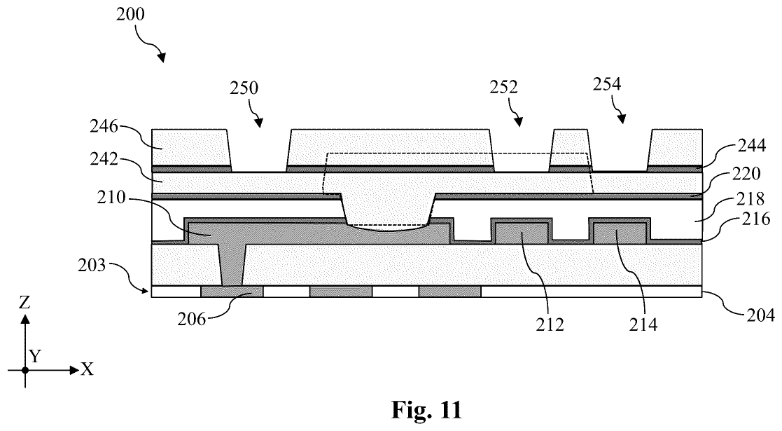

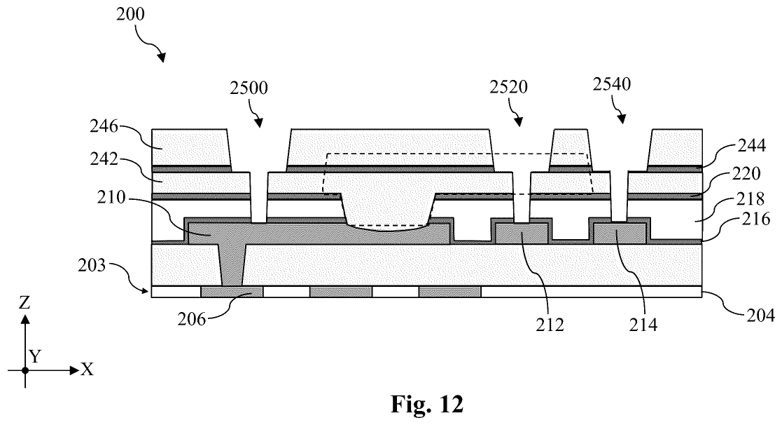

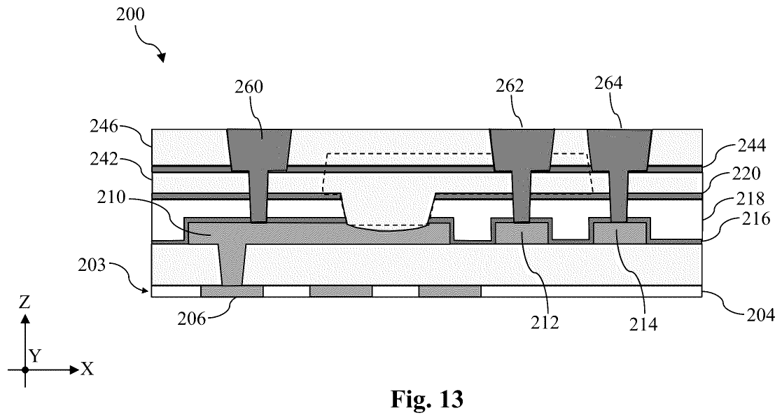

Referring to FIGS. 1 and 11-13 method 100 includes a block 114 where via features 260, 262 and 264 are formed through the dielectric layers. Operations at block 114 may include forming of a first trench 250, a second trench 252, and a third trench 254 through the third dielectric layer 246 and the second ESL 244 (shown in FIG. 11), extending the first trench 250, second trench 252, and third trench 254 through the second dielectric layer 242, the first ESL 220, and the first dielectric layer 218 to form first, second and third dual damascene openings 2500, 2520 and 2540 (shown in FIG. 12), and deposition of conductive material in the dual damascene openings 2500, 2520, and 2540 (shown in FIG. 13). In an example process, the first trench 250, second trench 252, and third trench 254 are first formed by a combination of photolithography and etch steps. The etching through the third dielectric layer 246 and the second ESL 244 may be accomplished with a dry etch process that includes use of an oxygen-containing gas (e.g., O₂), a fluorine-containing gas (e.g., SF₆ or NF₃), or a chlorine-containing gas (e.g., Cl₂ and/or BCl₃). Each of the first trench 250, second trench 252, and third trench 254 is then extended downward with a via opening through the second dielectric layer 242, the first ESL 220, and the first dielectric layer 218. The etching through the second dielectric layer 242, the first ESL 220, and the first dielectric layer 218 may be accomplished with a dry etch process that includes use of an oxygen-containing gas (e.g., O₂), a fluorine-containing gas (e.g., SF₆ or NF₃), or a chlorine-containing gas (e.g., Cl₂ and/or BCl₃). Each of the first, second and third dual damascene openings 2500, 2520 and 2540 includes a trench opening (such as the first trench 250, second trench 252, and third trench 254) and a via opening that is in fluid communication with the overlying trench opening. Block 114 then proceed to deposit a metal fill layer into the first, second and third dual damascene openings 2500, 2520 and 2540 to form a first via feature 260, a second via feature 262, and a third via feature 264. In some embodiments, the metal fill layer may include copper (Cu), nickel (Ni), cobalt (Co), titanium (Ti), or aluminum (Al). In one embodiment, the metal fill layer may include copper (Cu). In some embodiments not explicitly illustrated in the figures, each of the first via feature 260, the second via feature 262, and the third via feature 264 may include a barrier layer to space apart from the first dielectric layer 218, the second dielectric layer 242, and the third dielectric layer 246, which includes oxygen. A planarization process, such as a chemical mechanical polishing (CMP) process, is performed to remove excess materials and provide a coplanar top surfaces for the third dielectric layer 246, the first via feature 260, the second via feature 262, and the third via feature 264.

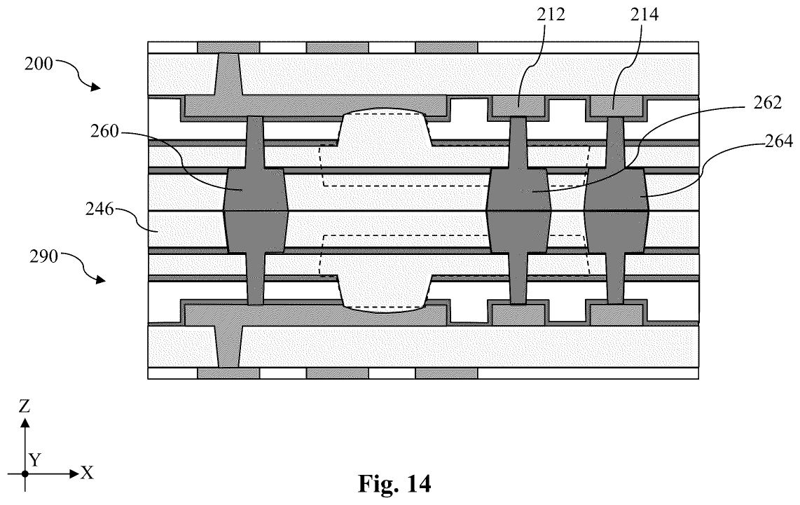

Referring to FIGS. 1 and 14, method 100 includes a block 116 where further processes are performed. Such further process may include directly bonding the WIP structure 200, as a die, to another die 290. FIG. 14 illustrates an example with the WIP structure 200 is flipped over and directly bonded to another die 290 that has similar via feature arrangements. To bond the WIP structure 200 and the die 290, surfaces of the third dielectric layer 246, the first via feature 260, the second via feature 262, and the third via feature 264 are cleaned to remove organic and metallic contaminants. For example, a sulfuric acid hydrogen peroxide mixture (SPM), a mixture of ammonium hydroxide and hydrogen peroxide (SC1), or both may be used to remove organic contaminants on surfaces of the third dielectric layer 246, the first via feature 260, the second via feature 262, and the third via feature 264. A mixture of hydrochloric acid and hydrogen peroxide (SC2) may be used to remove metallic contaminants. Besides cleaning, the planarized surfaces of the third dielectric layer 246, the first via feature 260, the second via feature 262, and the third via feature 264 may be treated by an argon plasma or a nitrogen plasma to activate the surfaces thereof. After the via features (and their counterparts in the die 290) are aligned vertically, an anneal is performed to promote the van der Waals force bonding of third dielectric layer 246s as well as the surface-activated bonding (SAB) of the first via feature 260, the second via feature 262, and the third via feature 264 (and their counterparts in the die 290). In some instances, the anneal includes a temperature between about 200° C. and about 300° C.

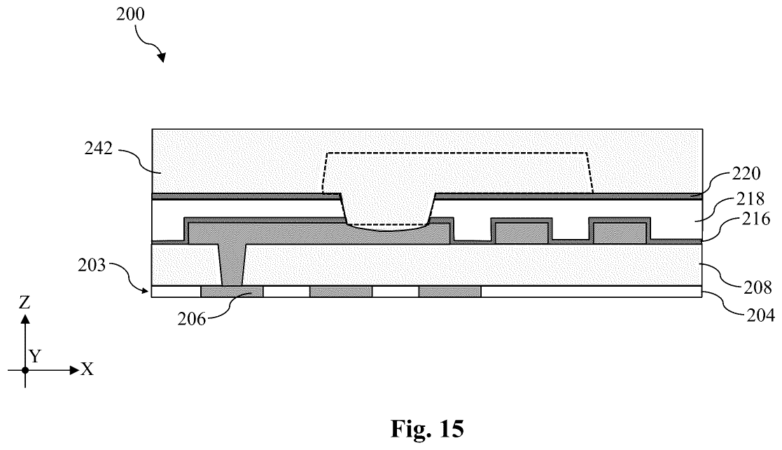

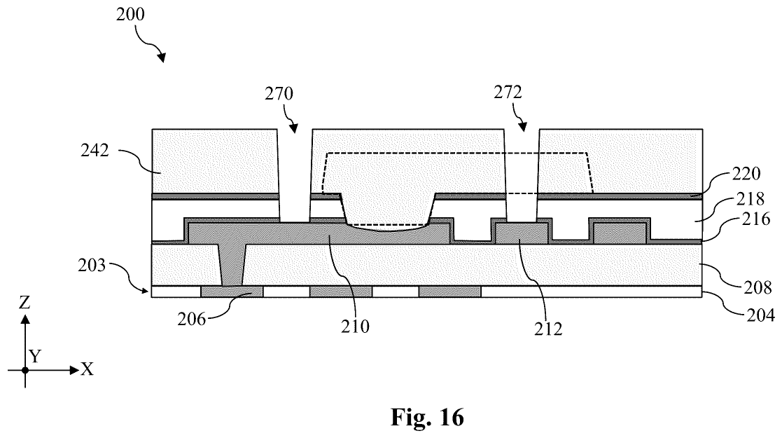

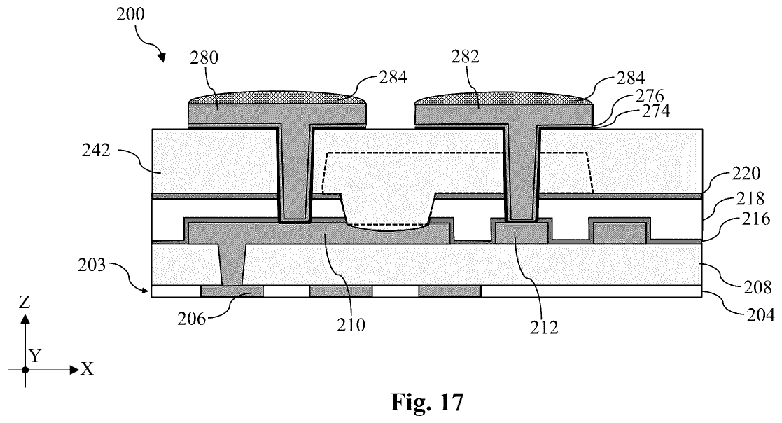

In some alternative embodiments, method 100 in FIG. 1 may be applied to form alternative structures where the WIP structure 200 is not bonded to another die by direct bonding. Reference is first made to FIG. 15. After the sacrificial pad 232 is removed, the second dielectric layer 242 is deposited over the first ESL 220 and the recess 240 at block 112. The second ESL 244 and the third dielectric layer 246 are not deposited over the second dielectric layer 242 in the embodiments represented in FIG. 15. The composition and deposition of the second dielectric layer 242 have been described above and will not be repeated here for brevity. Referring to FIG. 16, a first via opening 270 and a second via opening 272 are formed through the second dielectric layer 242, the first ESL 220, the first dielectric layer 218, and the dielectric liner 216 to expose top surfaces of the first redistribution feature 210 and the second redistribution feature 212, respectively. Formation of the first via opening 270 and the second via opening 272 may include a combination of photolithography and etch steps. The etching through the second dielectric layer 242, the first ESL 220, the first dielectric layer 218, and the dielectric liner 216 may be accomplished with a dry etch process that includes use of an oxygen-containing gas (e.g., O₂), a fluorine-containing gas (e.g., SF₆ or NF₃), or a chlorine-containing gas (e.g., Cl₂ and/or BC₁₃). A first contact pad 280 and a second contact pad 282 are then formed over the first via opening 270 and the second via opening 272, respectively at block 114. Formation of the first contact pad 280 and the second contact pad 282 may be similar to the formation of the sacrificial pad 232 described above. For example, a barrier layer 274 and a seed layer 276 are sequentially deposited over the first via opening 270 and the second via opening 272. After formation of a patterned mask, the first contact pad 280 and the second contact pad 282 are deposited using electroplating or electroless plating. A solder feature 284 is formed over each of the first contact pad 280 and the second contact pad 282. As shown in FIG. 17, each of the first contact pad 280 and the second contact pad 282 includes a via portion that extends through the second dielectric layer 242, the first ESL 220, the first dielectric layer 218, and the dielectric liner 216 to contact the first redistribution feature 210 and the second redistribution feature 212, respectively. For avoidance of doubt, the barrier layer 274 may be similar to the barrier layer 224; the seed layer 276 may be similar to the seed layer 226; and the metal in the first contact pad 280 and the second contact pad 282 may be similar to that in the sacrificial pad 232. Further processes at block 116 may include flipping the WIP structure 200 in FIG. 17 over and bonding the same to a circuit substrate 500 using the first contact pad 280 and the second contact pad 282. The circuit substrate 500 may be a silicon interposer.

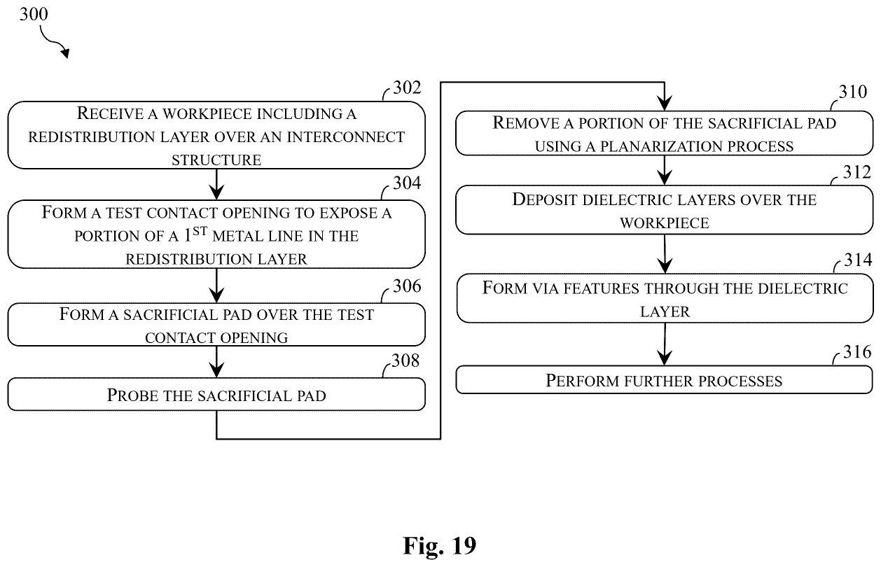

Method 300 in FIG. 19 is different from method 100 at least in that method 100 completely removes the sacrificial pad 232 after the probe testing is completed while method 300 removes a portion of the sacrificial pad using a planarization process. Method 300 shares several similar operations with method 100. For the sake of brevity, detailed description of these similar steps will be omitted.

Referring to FIGS. 19 and 2, method 100 includes a block 302 where a WIP structure 200 is received. Operations at block 302 are similar to those in block 102. For this reasons, detailed description of operations at block 302 is omitted for brevity.

Referring to FIGS. 19 and 2, method 300 includes a block 304 where a test contact opening 222 is formed to expose a portion of a first metal line 206 in the top metal layer 203. Operations at block 304 are similar to those in block 104. For this reasons, detailed description of operations at block 304 is omitted for brevity.

Referring to FIGS. 19 and 3-6, method 300 includes a block 306 where a sacrificial pad 232 is formed over the test contact opening 222. Operations at block 306 are similar to those in block 106. For this reasons, detailed description of operations at block 306 is omitted for brevity.

Referring to FIGS. 19 and 7, method 300 includes a block 308 where the sacrificial pad 232 is probed. Operations at block 308 are similar to those in block 108. For this reasons, detailed description of operations at block 308 is omitted for brevity.

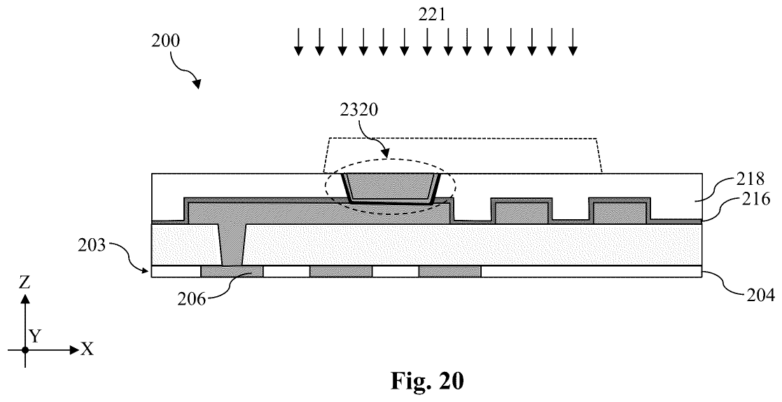

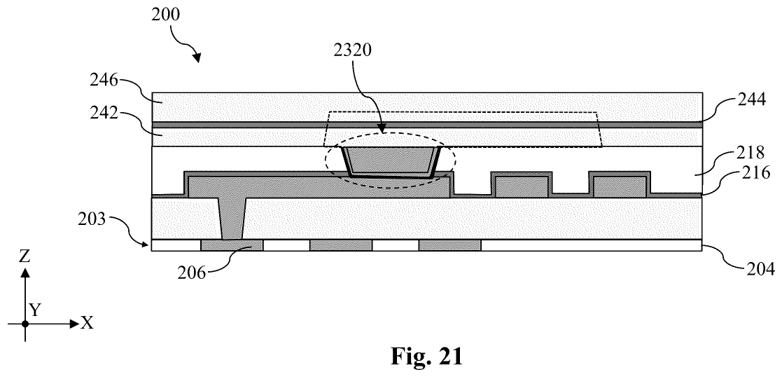

Referring to FIGS. 19 and 20, method 300 includes a block 310 wherein the sacrificial pad 232 is partially removed by a planarization process 221. Instead of etching the sacrificial pad 232 away, block 310 performs a planarization process 221, such as a chemical mechanical polishing (CMP) process, to the WIP structure 200 until top surfaces of a residual portion 2320 of the sacrificial pad 232 and the first dielectric layer 218 are coplanar. The residual portion 2320 includes all the layers in the sacrificial pad 232. As shown in FIG. 21, the residual portion 2320 includes the barrier layer 224, the seed layer 226, and the metal filler 232. While not explicitly shown in FIG. 20, a planarization dielectric layer may be deposited over the WIP structure 200, including over the sacrificial pad 232, before the planarization process is performed. At the end of the planarization process 221, the planarization dielectric layer is completely removed. In some instances, the planarization dielectric layer may include silicon oxide and may be deposited using CVD. As shown in FIG. 20, the residual portion 2320 may have a size substantially corresponding to that of the test contact opening 222 shown in FIG. 2. For example, the residual portion 2320 may have a width similar to the first width W1 of the test contact opening 222.

Referring to FIGS. 19 and 21, method 300 includes a block 312 where dielectric layers are deposited over the WIP structure 200. Operations at block 312 are similar to those in block 112. For this reasons, detailed description of operations at block 312 is omitted for brevity. In some embodiments represented in FIG. 21, the second dielectric layer 242 is deposited on top surfaces of the first dielectric layer 218 and the residual portion 2320.

Referring to FIGS. 19 and 22-23, method 300 includes a block 314 where via features 260, 262 and 264 are formed through the dielectric layers. Operations at block 314 are similar to those in block 114. For this reasons, detailed description of operations at block 314 is omitted for brevity.

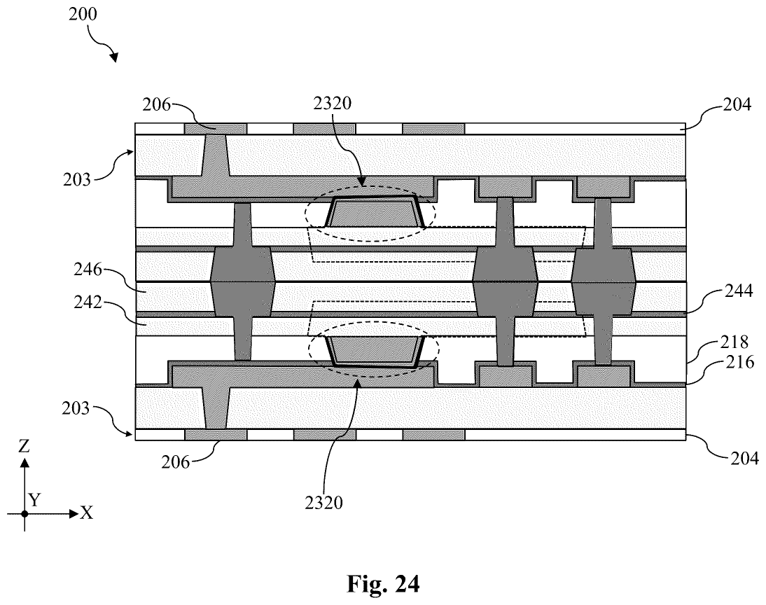

Referring to FIGS. 19 and 24, method 300 includes a block 316 where further processes are performed. Operations at block 316 are similar to those in block 116. For this reasons, detailed description of operations at block 316 is omitted for brevity. As shown in FIG. 24, the residual portion 2320 remains in the final structure. In some embodiments, the residual portion 2320 in the die below may be vertically aligned with a counterpart in the die above.

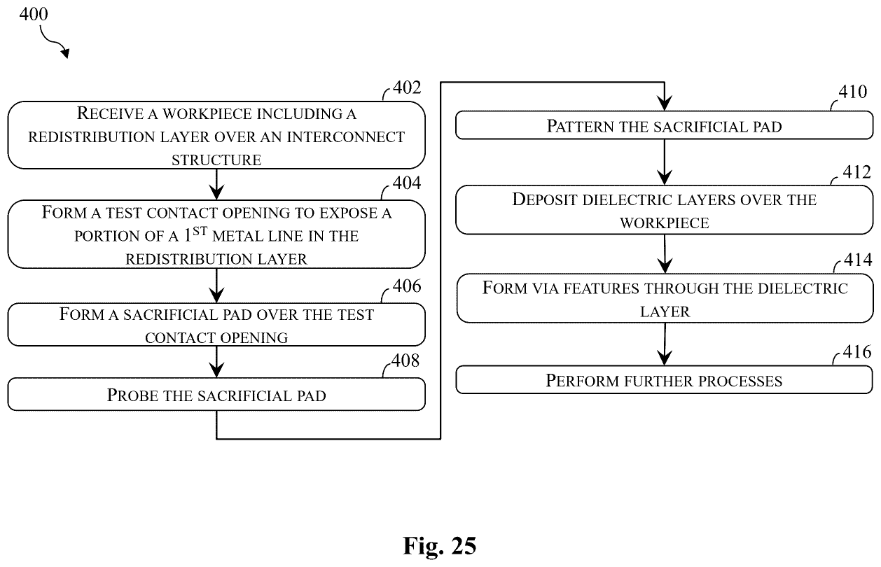

Method 400 in FIG. 25 is different from method 100 at least in that method 100 completely removes the sacrificial pad 232 after the probe testing is completed while method 400 patterns the sacrificial pad. Method 400 shares several similar operations with method 100. For the sake of brevity, detailed description of these similar steps will be omitted.

Referring to FIGS. 25 and 2, method 400 includes a block 402 where a WIP structure 200 is received. Operations at block 402 are similar to those in block 102. For this reasons, detailed description of operations at block 402 is omitted for brevity.

Referring to FIGS. 25 and 2, method 400 includes a block 404 where a test contact opening 222 is formed to expose a portion of a first metal line 206 in the top metal layer 203. Operations at block 404 are similar to those in block 104. For this reasons, detailed description of operations at block 404 is omitted for brevity.

Referring to FIGS. 25 and 3-6, method 400 includes a block 406 where a sacrificial pad 232 is formed over the test contact opening 222. Operations at block 406 are similar to those in block 106. For this reasons, detailed description of operations at block 406 is omitted for brevity.

Referring to FIGS. 25 and 7, method 400 includes a block 408 where the sacrificial pad 232 is probed. Operations at block 408 are similar to those in block 108. For this reasons, detailed description of operations at block 408 is omitted for brevity.

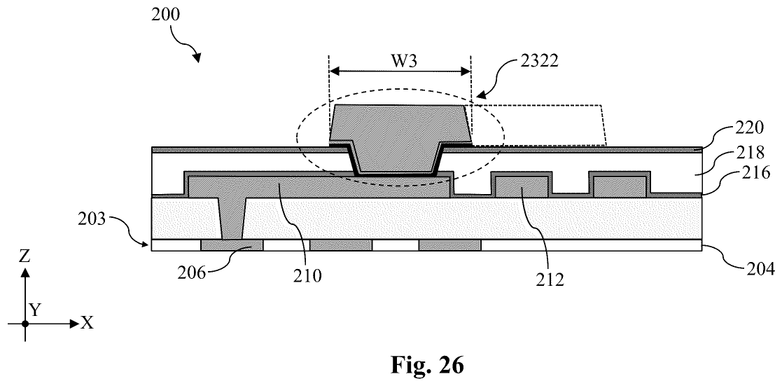

Referring to FIGS. 25 and 26, method 400 includes a block 410 wherein the sacrificial pad 232 is patterned. Instead of completely removing the sacrificial pad 232 in method 100 or planarizing the sacrificial pad 232 in method 300, method 400 reduces the footprint of the sacrificial pad 232 by patterning it. In some implementations, photolithography and etch processes are performed to remove a portion of the sacrificial pad 232 that overhangs the second redistribution feature 212. For example, a patterned etch mask may be formed over the sacrificial pad 232 by photolithography steps. Then the sacrificial pad 232 is etched using the patterned etch mask as an etch mask. The etching may be performed using a dry etch process, a wet etch process, or a combination thereof. An example dry etch process may include use of hydrogen plasma and nitrogen (N₂). As shown in FIG. 26, the patterning at block 410 results in a truncated pad 2322. The truncated pad 2322 has a third width W3, which is greater than the first width WI of the test contact opening 222 but is smaller than the second width W2 of the sacrificial pad 232. In some embodiments represented in FIG. 26, the truncated pad 2322 is of a small dimension such that it no longer overhangs the second redistribution feature 212.

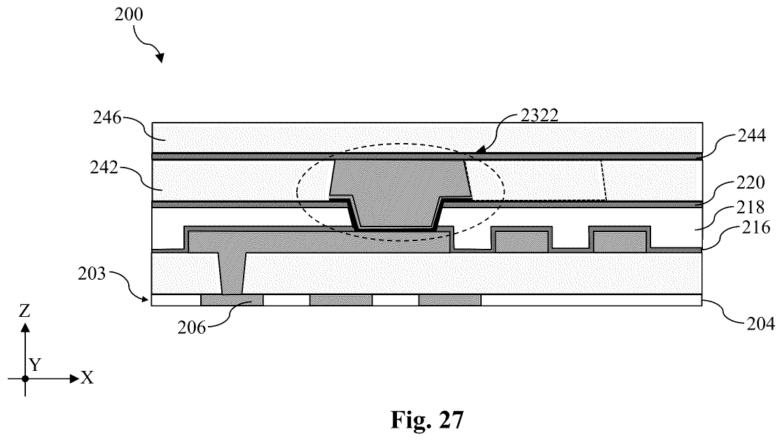

Referring to FIGS. 25 and 27, method 400 includes a block 412 where dielectric layers are deposited over the WIP structure 200. Operations at block 412 are similar to those in block 112. For this reasons, detailed description of operations at block 412 is omitted for brevity. In some embodiments represented in FIG. 27, the second dielectric layer 242 is disposed around the truncated pad 2322. The second dielectric layer 242 is in direct contact with sidewalls of the truncated pad 2322. The second ESL 244 may be deposited on top surfaces of the truncated pad 2322 and the second dielectric layer 242.

Referring to FIGS. 25 and 28-29, method 400 includes a block 414 where via features 260, 262 and 264 are formed through the dielectric layers. Operations at block 414 are similar to those in block 114. For this reasons, detailed description of operations at block 414 is omitted for brevity.

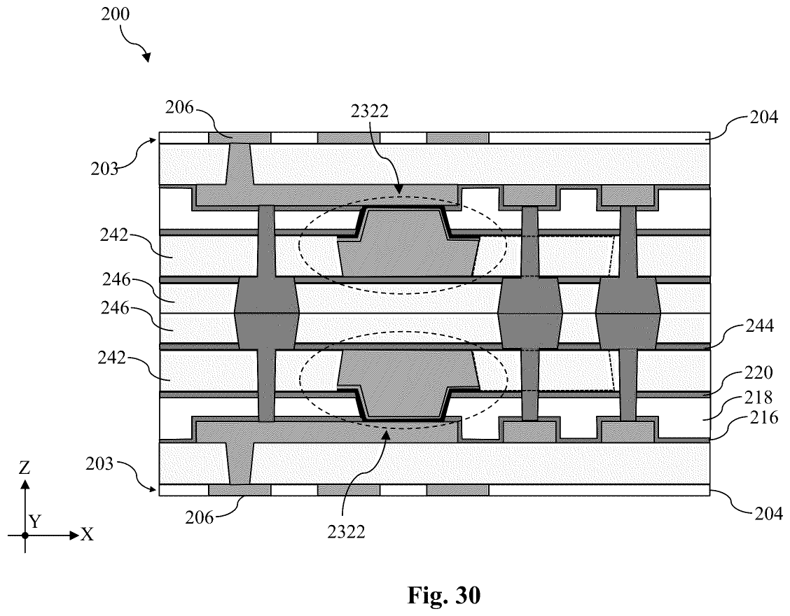

Referring to FIGS. 19 and 30, method 300 includes a block 416 where further processes are performed. Operations at block 416 are similar to those in block 116. For this reasons, detailed description of operations at block 416 is omitted for brevity. As shown in FIG. 30, the truncated pad 2322 remains in the final structure. In some embodiments, the truncated pad 2322 in the die below may be vertically aligned with a counterpart in the die above.

One aspect of the present disclosure involves a redistribution structure. The redistribution structure includes a metal line, a first dielectric layer disposed over the metal line, a first etch stop layer (ESL) disposed over the first dielectric layer, a second dielectric layer disposed over the first ESL, and a conductive via extending through the second dielectric layer, the first ESL and the first dielectric layer to contact the metal line. A lower portion of the second dielectric layer extends downward through the first ESL and the first dielectric layer and partially into the metal line.

In some embodiments, the redistribution structure further includes a dielectric liner sandwiched between the first dielectric layer and surfaces of the metal line. In some implementations, the lower portion of the second dielectric layer also extends through the dielectric liner. In some instances, the dielectric liner includes silicon nitride and the dielectric liner includes a thickness between about 100 nm and about 200 nm. In some embodiments, the dielectric liner is disposed over and in contact with sidewalls of the metal line. In some embodiments, the lower portion of the second dielectric layer is in direct contact with sidewalls of the first ESL, the first dielectric layer, and the dielectric liner. In some embodiments, the metal line is disposed over a passivation layer, the passivation layer includes silicon nitride, and the passivation layer includes a thickness between about 1 μm and about 2 μm. In some embodiments, the lower portion includes a width between about 10 μm and about 20 μm. In some instances, the metal line includes copper (Cu).

Another aspect of the present disclosure involves a contact structure. The contact structure includes a passivation layer, a metal line disposed over the passivation layer, a first dielectric layer disposed over the metal line, a metal feature disposed in the first dielectric layer and in contact with a top surface of the metal line, a second dielectric layer disposed over top surfaces of the first dielectric layer and the metal feature, and a conductive via extending through the second dielectric layer and the first dielectric layer to contact the metal line. The top surfaces of the first dielectric layer and the metal feature are coplanar.

In some embodiments, the metal feature includes a barrier layer in direct contact with the first dielectric layer and the metal line, a seed layer disposed on the barrier layer, and a metal fill layer over the seed layer. In some embodiments, the second dielectric layer is in contact with the barrier layer, the seed layer, and the metal fill layer. In some implementations, the barrier layer includes titanium (Ti), tantalum (Ta), or tantalum nitride (TaN) and the seed layer and the metal fill layer include copper (Cu). In some embodiments, the metal feature includes a width between about 10 μm and about 20 μm. In some embodiments, the contact structure further includes a dielectric liner sandwiched between the first dielectric layer and surfaces of the metal line. In some instances, the metal feature extends through the dielectric liner to contact the top surface of the metal line.

Still another aspect of the present disclosure involves a method. The method includes depositing a first dielectric layer over a metal line, depositing a first etch stop layer (ESL) over the first dielectric layer, forming a test contact opening through the first dielectric layer and the first ESL to expose a portion of the metal line, forming a test pad over the test contact opening, performing a test by causing a probe to contact the test pad, after the performing of the test, removing the test pad to expose the test contact opening, and after the removing of the test pad, depositing a second dielectric layer over the first ESL and the test contact opening.

In some embodiments, the forming of the test pad includes depositing a barrier layer over the test contact opening and the first ESL, depositing a seed layer over the barrier layer, and depositing a metal fill layer over the seed layer using electroplating. In some embodiments, the removing of the test pad extends the test contact opening into the metal line. In some implementations, after the depositing of the second dielectric layer, a portion of the second dielectric layer extends below a top surface of the metal line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A contact structure, comprising:
a redistribution feature;
a first dielectric layer surrounding a top portion of the redistribution feature;
a second dielectric layer disposed over a top surface of the first dielectric layer; and
a metal feature extending through the first dielectric layer and the second dielectric layer to contact the redistribution feature, wherein top surfaces of the second dielectric layer and the metal feature are coplanar.

2. The contact structure of claim 1, further comprising an etch stop layer (ESL) disposed between the first dielectric layer and the second dielectric layer, wherein a portion of the metal feature extends along a top surface of the ESL.

3. The contact structure of claim 1, further comprising a passivation layer surrounding a bottom portion of the redistribution feature.

4. The contact structure of claim 1, wherein the metal feature comprises metal fill layer over a barrier layer.

5. The contact structure of claim 4, wherein:
a first sidewall of the metal fill layer embedded in the second dielectric layer is free of contact with the barrier layer, and
a second sidewall of the metal fill layer embedded in the first dielectric layer is lined with the barrier layer.

6. The contact structure of claim 4, wherein a portion of the barrier layer extends along the top surface of the first dielectric layer.

7. The contact structure of claim 4, further comprising a seed layer disposed between the metal fill layer and the barrier layer.

8. The contact structure of claim 1, further comprising an etch stop layer (ESL) disposed over an entire top surface of the metal feature.

9. The contact structure of claim 1, further comprising a conductive via extending through the second dielectric layer to contact the redistribution feature.

10. A redistribution structure, comprising:
a metal line;
a first dielectric layer disposed over the metal line;
a second dielectric layer disposed over a top surface of the first dielectric layer; and
a metal feature in contact with the metal line, wherein:
a top portion of the metal feature is embedded in the first dielectric layer, and
a bottom portion of the metal feature is embedded in the second dielectric layer.

11. The redistribution structure of claim 10, further comprising a dielectric liner sandwiched between the first dielectric layer and surfaces of the metal line.

12. The redistribution structure of claim 11, wherein the bottom portion of the metal feature also extends through the dielectric liner.

13. The redistribution structure of claim 10, wherein:
the metal feature comprises a metal fill layer over a barrier layer, and
the barrier layer separates a first sidewall of the metal fill layer from the first dielectric layer.

14. The redistribution structure of claim 13, wherein a second sidewall of the metal fill layer directly interfaces with the second dielectric layer.

15. The redistribution structure of claim 10, further comprising an etch stop layer (ESL) interposed between the first dielectric layer and the second dielectric layer.

16. The redistribution structure of claim 15, wherein the top portion of the metal feature interfaces with a top surface of the ESL.

17. A method, comprising:
forming a first dielectric layer over a metal line;
forming a test contact opening through the first dielectric layer to expose a portion of the metal line;
forming a test pad over the test contact opening;
removing a portion of the test pad such that a remaining portion of the test pad comprising a top portion above a top surface of the first dielectric layer and a bottom portion below the top surface of the first dielectric layer; and
forming a second dielectric layer over the remaining portion of the test pad, wherein top surfaces of the second dielectric layer and the remaining portion of the test pad are coplanar.

18. The method of claim 17, further comprising forming an etch stop layer (ESL) over the top surfaces of the second dielectric layer and the remaining portion of the test pad.

19. The method of claim 17, further comprising forming an etch stop layer (ESL) between the first dielectric layer and the second dielectric layer, wherein the top portion of the remaining portion of the test pad extends along a top surface of the ESL.

20. The method of claim 17, further comprising forming a conductive via extending through the second dielectric layer to contact the metal line.
